(19) United States
(12) Patent Application Publication
(10) Pub. No.: US 2003/0161379 A1
(43) Pub. Date: Aug. 28, 2003

(54) Laser package

(75) Inventors: Edmund L. Wolak, Palo Alto, CA (US); Nina Morozova, San Jose, CA (US); Jay A. Skidmore, San Jose, CA (US); Ning Yao Fan, Victoria (CA); Jo S. Major JR., Cupertino, CA (US); Robert J. Lang, Alamo, CA (US); Garnet Scott Luick, Victoria (CA); Donald C. Hargreaves, San Jose, CA (US); Vincent V. Wong, San Jose, CA (US); Richard L. Duesterberg, Mountain View, CA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: JDS Uniphase Corporation, San Jose, CA

(21) Appl. No.: 10/326,197

(22) Filed: Dec. 20, 2002

Related U.S. Application Data
(60) Provisional application No. 60/342,563, filed on Dec. 26, 2001.
(60) Provisional application No. 60/372,017, filed on Apr. 12, 2002.

(51) Int. Cl. H01S 5/00; H01S 3/08

(52) U.S. Cl. 372/108; 372/43

(57) ABSTRACT

The invention provides a laser package having a single-mode laser diode for emitting light; a single-mode optical fiber comprising an uncoated microlens formed on an input end of said single-mode optical fiber, the microlens optically coupled to the laser diode for receiving the light, the microlens being constructed so as to reduce a level of back reflection into the laser diode so as not to disturb an operation of the laser diode, wherein a center axis of the single-mode optical fiber is co-planar with an optical axis of the laser diode; and a grating formed in the single-mode optical fiber for providing feedback to the laser diode to stabilize the emitted light from the laser diode. The single-mode optical fiber can include a length of polarization maintaining fiber between the grating and the single-mode laser diode.

### CROSS-REFERENCE TO RELATED APPLICATIONS

This application claims priority of U.S. Provisional Patent Application No. 60/342,563 filed on Dec. 26, 2001 entitled “Method Of Reducing Tracking Error” and U.S. Provisional Patent Application No. 60/372,017 filed on Apr. 12, 2002, entitled “High Power Fiber Amplifier Pump Module with Improved Spectral Locking and Kink-Free Performance” which are incorporated herein by reference for all purposes.

### MICROFICHE APPENDIX

Not Applicable

### FIELD OF THE INVENTION

The present invention generally relates to the field of laser modules and in particular to a laser package having a planar design.

### BACKGROUND OF THE INVENTION

In the employment of pump laser modules, such as 980 nm and 1480 nm pump modules, it is necessary to insure that the output intensity of the pump laser is maintained at a desired level. It is additionally desired that the spectrum be maintained at a controlled wavelength.

Monitoring of the output intensity is accomplished by use of a monitor device, such as a monitor photo diode, positioned at the back facet of the laser diode chip, or elsewhere within the package positioned so as to capture a portion of the light emitted by the laser diode, either directly or scattered from the optical fiber or from other parts of the package.

In order to minimize the effects of spurious reflections from the fiber tip that are coupled back into the laser diode, it is desirable to shape the tip of the fiber in such a way that reflections are reduced, such as forming an angled chisel on the fiber tip, a biconic lens, or an offset biconic lens, as described in U.S. patent application Ser. Nos. 09/915,184 and 09/915,186, incorporated herein by reference for all purposes.

Tracking error arises in general from uncontrolled reflections that make their way back into the laser diode where phase, polarization and/or magnitude of said reflections are a function of the temperature of the package case. An additional source of tracking error can result from changes in the polarization state of fed-back light. In a typically fiber-grating-stabilized pump laser, a fiber Bragg grating is located in the fiber some distance from the laser diode, whose purpose is to reflect a given amount of light back toward the laser within a narrow band of frequencies. This narrowband feedback stabilizes the optical spectrum of the laser, and in doing so, improves the intensity stability of the laser.

However, when the fiber is coiled or otherwise manipulated, it experiences stress-induced birefringence, which alters the polarization state of the fed-back signal to the laser. This effect can vary with time and temperature, resulting in a reduction in stability of the laser. It is well known in the art that the effect of stress-induced birefringence can be avoided by using polarization-maintaining fiber between the laser diode and the fiber Bragg grating. Use of PM fiber in concert with a fiber Bragg grating is disclosed in U.S. Pat. No. 5,659,559, “Apparatus for generating a stabilized laser source”, by Brian Ventrudo and Grant Rogers, which is incorporated herein by reference.

Hence, polarization control is useful to further stabilize pump lasers. The light emitted from the output facet of the diode lasers is typically highly polarized. The polarization of the light propagating through regular, non-polarization maintaining fiber, however, can change its orientation due to fiber birefringence, fiber twisting, bending, temperature shifts, and other stresses. Any fluctuation in the polarization of the light returning to the optical device from the grating effectively changes the feedback power ratio, because the laser is insensitive to any reflected light that has a polarization orthogonal to that of the emitted light. For example, if all of the reflected light has its polarization rotated by 90 degrees, the fiber Bragg grating is effectively removed from the system from the laser's perspective.

In applications where polarization control is required between the laser diode and the grating, polarization-maintaining (PM) fiber is used for the fiber pigtail, with the grating being written into the PM fiber.

While the use of polarization-maintaining (PM) fiber has been used for coupling of fiber-Bragg grating stabilized lasers to reduce intensity noise, it has only been used with conventional fiber lens tips such as conical or ordinary chisel lenses. Thus, the use of PM fiber has not been used in connection with methods of reducing tracking error and reducing spectral instability related to fiber end reflections.

Optical coupling schemes that require high efficiency typically utilize a lensed fiber that is attached in close proximity (planar design) to the light source, e.g. a laser diode., or discreet bulk lenses between the laser and the fiber (coaxial design).

Two key aspects in the coupling of optical radiation from a semiconductor laser diode to an optical fiber are the efficiency of the coupling, and the level of back reflection of radiation from the optical fiber to the laser diode. Various techniques are known for reducing the level of back reflection, or for increasing the coupling efficiency. A known technique for reducing the level of back reflection is to arrange for the optical radiation to strike the fiber end face at an angle other than 90, either by tilting the optical fiber with respect to the laser diode, and/or by polishing the end face of the optical fiber obliquely. Another known technique to reduce Fresnel reflection is to provide an anti-reflection coating on the fiber end face. Hence, an anti-reflective (AR) coating is usually provided on a lens tip to reduce the loss of light propagating through the interface and to avoid back reflections to the laser diode so as not to disturb the oscillation of the laser.

U.S. Pat. No. 5,479,549 to Kurata discloses a coupling structure and method to directly couple a semiconductor laser to an optical fiber without using a lens. In the method of directly coupling a semiconductor laser to an optical fiber, however, a return light caused by Fresnel reflection at a mirror-polished end face of the optical fiber may be re-combined in an oscillator portion of the semiconductor laser, causing an oscillating state of the semiconductor laser to be unstable. Kurata discloses, that one method of reducing the influence of reflection light is to provide an anti-reflection coating on the end face of the optical fiber. However, this patent further teaches that the producibility of this method is very low since such coating is provided by attaching an anti-reflection film on the end face or vapor-depositing it thereon. The solution taught by Kurata to avoid an anti-reflective coating is to increase the surface roughness of the fiber end face. With such irregularity, Fresnel reflection light is scattered when it is reflected. Therefore, there is no light returned to an oscillator portion of the semiconductor laser and the influence of return light is removed. However, increasing the surface roughness of the fiber end face does not provide for an efficient coupling of light between the laser diode and the fiber pigtail.

U.S. Pat. No. 5,940,557 to Harker teaches the use of an optical fiber microlens having anamorphic focusing means that have a major axis that is not perpendicular to the longitudinal axis of the optical fiber to couple light from the laser to the fiber. In particular, a wedge-shaped optical fibre microlens whose tip is skewed with respect to the longitudinal axis of the optical fibre, is described in this patent. Anamorphic optical fiber microlenses have been developed to efficiently couple radiation from laser sources having asymmetric output radiation patterns. Harker further discloses that other known techniques to reduce Fresnel reflection include the provision of an anti-reflection coating on the fiber end face.

U.S. Pat. No. 6,332,721 to Inokuchi discloses a laser diode module having a coaxial design. Such a laser diode module has a laser diode light source, an optical fiber on one end of which a convex fiber lens for condensing light is formed, and a lens system for coupling which is placed between the laser diode source and the convex fiber lens wherein the lens system is constituted to be capable of forming an image by condensing the laser diode light from the laser diode chip, and wherein the convex fiber lens is located so that a focal point coincides with the image forming point of the laser diode light. Inokuchi further discloses that the convex fiber lens has an anti-reflective coating on a surface of the lens. However, Inokuchi discloses a further design wherein an antireflective coating is not necessary, depending on whether in the optical fiber having a lens according to Inokuchi, a tip end surface may be perpendicular or not perpendicular to the optical axis. A preferable design is that the tip end surface is not perpendicular to the optical axis. Where such a design is used, reflected light does not return directly to the laser light source because of the inclined tip end surface even where a part of the laser light radiated from the laser light source is reflected at the tip end surface, so that the laser light source can keep its stability. Therefore, where a design that the tip end surface does not intersect with the optical axis with a right angle is used, an anti-reflection coating (AR coating) formed on a tip of the fiber may be unnecessary to maintain the stability of the laser light source. Therefore, unless an angled design is used in a coaxial laser diode module, an anti-reflective coating is required to reduce the back reflection into the laser cavity.

U.S. Pat. No. 6,400,746 to Yang discloses a pump laser that is stabilized with a fiber grating having a relatively low reflectivity. The pump module disclosed by Yang includes a laser diode chip, an optical fiber system into which the output light from the laser is coupled, and a grating written into the optical fiber of the fiber system. The optical fiber system includes a fiber microlens to ensure a high collection efficiency for light exiting from the light output facet of the laser diode. Yang further teaches that the fiber pigtail is preferably constructed from polarization-maintaining fiber. However, the fiber pigtail can also be constructed from regular fiber.

The coupling efficiency between the fiber pigtail and the diode laser has also an effect on the stabilization of a diode laser. For example, back reflections from the lens tip into the laser diode cause a variation in the coupled power due to the weak Fabry-Perot cavity formed between the lens tip and the front facet of the laser diode. Commonly, an anti-reflective coating is placed on an input end face of a lens to optimize the coupling efficiency. It is generally assumed in the art that an anti-reflective coating on the lens tip is particularly advantageous for high power laser configurations. However, the placement of an anti-reflective coating on an end face of a lens causes higher manufacturing and material costs. Furthermore, failures due to optical coating issues may be a problem in high power laser applications.

Hence, it is an object of the present invention to provide a laser module with improved reliability.

It is a further object of the invention to provide a high power laser module with improved reliability.

Another object of the invention is to provide a laser module with reduced manufacturing and material costs.

### SUMMARY OF THE INVENTION

In accordance with the invention there is provided, a laser package comprising a single-mode laser diode for emitting light; a single-mode optical fiber comprising an uncoated lens formed on an input end of said single-mode optical fiber, said lens optically coupled to the laser diode for receiving said light, said lens being constructed so as to reduce a level of back reflection into the laser diode so as not to disturb an operation of the laser diode, wherein a center axis of the single-mode optical fiber is co-planar with an optical axis of the laser diode; and a grating formed in the single-mode optical fiber for providing feedback to the laser diode to stabilize the emitted light from the laser diode.

In accordance with another embodiment of the invention, the single-mode laser diode is a high power single-mode laser diode. For example, the single-mode laser diode operates at an operating current of at least 360 mW.

In accordance with a further embodiment of the invention, the single-mode optical fiber comprises a length of polarization maintaining fiber between the grating and the single-mode laser diode. Alternatively, the single-mode optical fiber comprises only regular optical fiber between the laser diode and the grating.

In yet another embodiment of the invention, the laser package further comprising a light monitor optically coupled to the single-mode laser diode for monitoring an output power of the light emitted from the laser diode. For example, a monitor photo diode (MPD) can be used as the light monitor.

In accordance with another embodiment of the invention, the laser diode is a 980 nm pump laser or a 1480 nm pump laser.

In accordance with an embodiment of the invention, the uncoated lensed fiber tip or microlens is a chisel lens, an angled chisel lens, a pointed chisel lens, a double chisel lens, a biconic lens, an angled biconic lens, an offset biconic lens, a Fresnel lens, a binary Fresnel lens, a toric lens, an a-toric lens, an offset toric lens, or an offset a-toric lens.

In accordance with the invention, there is further provided, a planar laser package comprising a single-mode diode laser for emitting a beam of light; a single-mode optical fiber optically coupled to the single mode diode laser, said single mode optical fiber having an uncoated microlens formed at an end face closest to the single-mode diode laser for receiving said beam of light, the microlens being constructed so as to reduce a level of back reflection into the single-mode laser diode; and a fiber Bragg grating written into the single mode optical fiber for providing feedback to the single-mode laser diode for stabilizing the beam of light; wherein the single-mode optical fiber comprises a length of polarization-maintaining fiber between the single-mode laser diode and the fiber Bragg grating.

Furthermore, in accordance with the invention, there is provided, a laser package comprising a single-mode laser diode source for emitting light; a single-mode optical fiber optically coupled to the single-mode laser diode source for receiving said light; the single-mode laser diode source and the single-mode optical fiber being in a planar arrangement, wherein said single-mode optical fiber comprises an uncoated angled chisel lens, an uncoated angled biconic lens, or an uncoated offset biconic lens at an end face closest to the laser diode; and a fiber Bragg grating formed within a portion of said single-mode optical fiber for providing feedback to said single-mode laser diode source, wherein the single-mode optical fiber comprises a length of polarization-maintaining fiber between the single-mode laser diode and the fiber Bragg grating.

### BRIEF DESCRIPTION OF THE DRAWINGS

Exemplary embodiments of the invention will now be described in conjunction with the following drawings wherein like numerals represent like elements, and wherein:

FIG. 1 shows a schematic view of a prior art laser diode package 100 wherein the laser diode 110 and the fiber 120 having a lensed tip 130 are arranged in a co-axial design;

FIG. 2 shows a schematic view of a laser module in accordance with the invention having a planar architecture;

FIG. 3A is a perspective view of a biconic lensed fiber end or tip in accordance with one aspect of this invention;

FIG. 3B is a side view of the biconic lensed fiber end shown in FIG. 3A

FIG. 3C is a plan view of the biconic lensed fiber end shown in FIG. 3A

FIG. 4A is a plan view of a lensed fiber end in conjunction with a laser diode where the center axis of the lens is fractionally offset from the center axis of the optical fiber;

FIG. 4B is a plan view of an angled chisel-shaped lensed fiber end of the type disclosed in U.S. Pat. No. 5,940,577;

FIG. 4C is a simplified top view of a lensed optical fiber according to an embodiment of the present invention illustrating an offset center of the radius of the lens;

FIG. 4D is a simplified side view of the lensed fiber illustrated in FIG. 4C showing the core of the optical fiber centered with respect to the curve of the lens;

FIG. 5A is a plan view of an angled chisel or wedged shaped lensed fiber end where a side portion of the lens is cut away for angular positioning relative to the laser diode chip front facet;

FIG. 5B is a side view of the angled wedged-shape lensed fiber end shown in FIG. 5A;

FIG. 5C is an input end view of the angled wedged-shape lensed fiber end shown in FIG. 5A;

FIG. 6A is a simplified top view of a lensed optical fiber according to an embodiment of the present invention;

FIG. 6B is a simplified cross section of the lensed optical fiber of FIG. 6A illustrating a pointed chisel lens;

FIG. 6C is an enlarged portion of the cross section illustrated in FIG. 6B;

FIG. 6D is a simplified top view of a lensed optical fiber with a double chisel lens, according to another embodiment of the present invention;

FIG. 6E is a simplified top view of an optical fiber with an integrated Fresnel-type lens;

FIG. 7 presents a schematic view of a planar laser package including an uncoated angled chisel lens having a polarization-maintaining fiber pigtail with an integrated Bragg grating coupled to a laser diode;

### DETAILED DESCRIPTION OF THE PREFERRED EMBODIMENTS

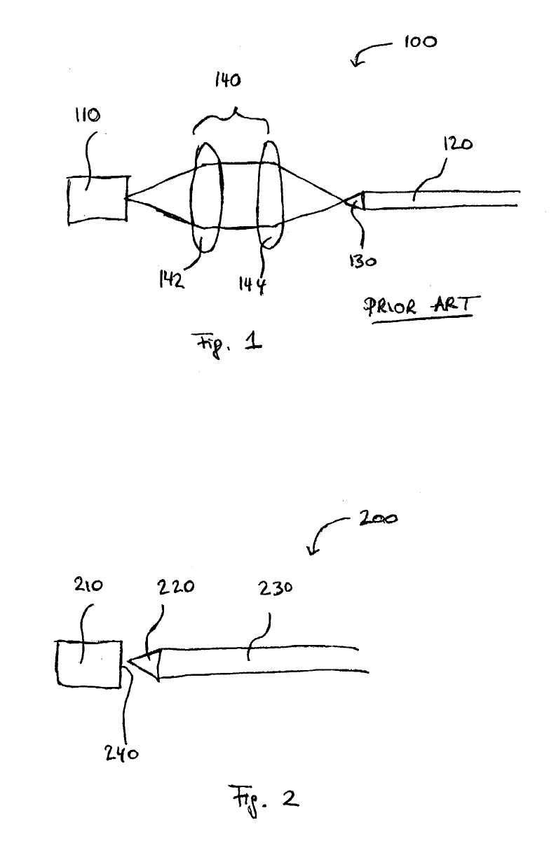

FIG. 1 shows a schematic view of a prior art laser diode package 100 wherein the laser diode 110 and the fiber 120 having a lensed tip 130 are arranged in a co-axial design by providing a lens system 140 between the laser diode 110 and the lensed fiber end 130. The lens system 140 includes two lenses 142, 144 for collimating the light emitted from the laser diode and for focussing it on the lensed tip 130 of fiber 120. The co-axial arrangement of a laser module as depicted in FIG. 1 provides for a relatively large distance between the laser facet and the lensed tip of fiber 130 of fiber 120. Such a co-axial arrangement is disclosed by Inokuchi in U.S. Pat. No. 6,332,721. Inokuchi teaches, as was explained heretofore, that where the tip end surface is not perpendicular to the optical axis, an anti-reflective (AR) coating may not be necessary because the reflected light does not return directly to the laser light source because of the inclined tip end surface. However, because of the relatively large distance between the laser facet and the fiber tip, even a small angle on the tip end surface provides a relatively large offset.

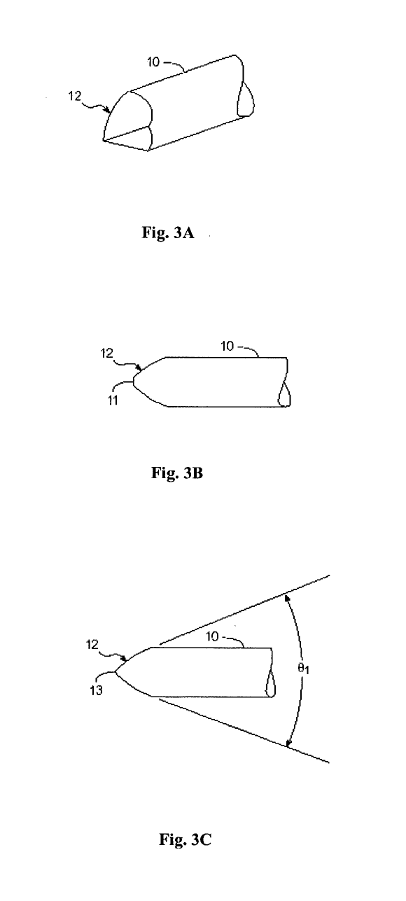

Turning now to FIG. 2, a schematic view of a laser module 200 in accordance with the invention is shown. Laser module 200 has a planar architecture wherein a lensed fiber tip 220 provided at an end of fiber 230 is brought into close proximity to an output facet 240 of a laser diode 210. The center axis of the optical fiber is co-planar with the optical axis of the laser diode. Typically, the distance between the laser diode and the fiber is approximately 8-10 μm in the planar architecture. Thus, in a planar design, a person of ordinary skill in the art would expect a problem with back reflection from the lens tip into the laser cavity even if an end face of the lens tip would be provided with an angle. Therefore, an AR coating is commonly provided on the lensed fiber tip of a laser module having a planar design so as to reduce an amount of Fresnel reflection back into the laser cavity. However, at high pump intensities, the AR coating can suffer some damage because of the high power density in the planar design.

In accordance with the present invention, it was discovered that an AR coating on the lensed fiber tip can be eliminated while still maintaining all performance specifications of the laser module. Hence, the present invention provides a laser package having a planar design using an uncoated microlens at an end face of a fiber in close proximity to an output facet of a laser diode. The use of an uncoated lensed fiber tip provides several advantages, such as an increased reliability of the laser package as the damage threshold is increased, as well as lower manufacturing and material cost as a result of omitting the AR coating. In accordance with the present invention, it was found that a fiber tip blowout failure of the laser modules was reduced as a result of omitting the AR coating on the lensed fiber tip. Employing a Tensed fiber whose shape scatters reflected light away from the laser chip, it is possible to use an uncoated fiber tip while tolerating the Fresnel reflection from the fiber tip. The uncoated lens is constructed so as to produce minimal feedback into the optical cavity of a laser diode, such as a fiber amplifier pump module. This allows the following performance improvements of spectral locking over a wide range of operating powers and temperatures, high kink free power independent of fiber lay, and an increased damage threshold at a high optical irradiance on the fiber facet.

Eliminating the AR coating at the Tensed fiber tip causes a higher percentage of Fresnel reflection. Hence, the microlens employed at the fiber tip is constructed so as to reduce a level of back reflection into the laser diode so as not to disturb an operation of the laser diode by destabilizing it. Examples of suitable microlenses, such as angled chisel lenses, angled biconic lenses, offset biconic lenses, toric and a-toric lenses, offset toric or a-toric lenses, or Fresnel lenses, that provide reduced back-reflections into the laser diode are disclosed in U.S. Pat. No. 5,940,557 to Harker, in U.S. patent application Ser. No. 09/915,184 entitled “Tracking Error Suppression And Method Of Reducing Tracking Error” by E. Wolak et al., and U.S. patent application Ser. No. 09/915,186 entitled “Lensed Optical Fiber” by E. Wolak. et al., the disclosures of which are incorporated herein by reference.

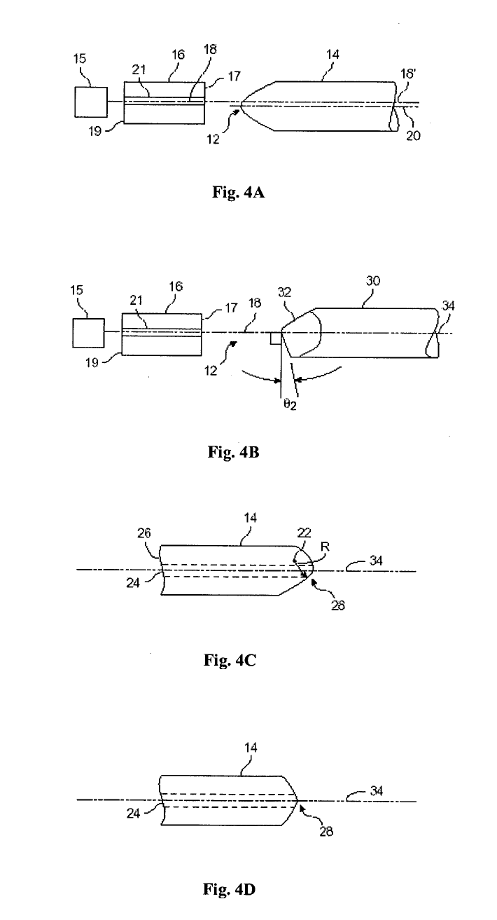

Reference is now made to FIG. 3A wherein there is shown a lensed fiber end 10 or tip comprising a biconic lens 12. The lens is formed on the fiber using special processing steps to form the curvatures of the lens surfaces and has a shape similar to a weathered pyramid. The biconic lens 12 has curvatures that are different in orthogonal directions as depicted in FIGS. 3B and 3C. In one orthogonal direction, as shown in FIG. 3B, a first radius of curvature 11 is 14 μm whereas in the other orthogonal direction a second radius of curvature 13 is 8 μm, with a tapered angle Θ₁ of about 50° to 55°. The larger radius in the plane of the lens may be, for example, around 12-22 μm while in the side elevation orthogonal to this plane the radius of curvature may be, for example, around 5-10 μm.

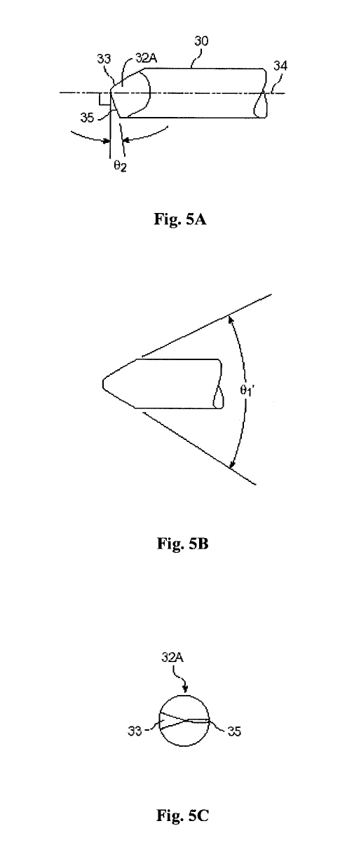

As shown in FIG. 4A, the biconic fiber lensed input end 10 of pigtail fiber 14 is positioned in front of the laser diode 16 to receive the light output from the diode via front facet 17. Laser diode 16 also includes a back facet 19, which has a highly reflective (HR) coating on it surface to reflect around 93-98% of the laser cavity light back into the laser cavity 21. However, 2% to 7% of the light penetrates through the back facet 19 and is received by laser monitor 15, for example, a monitor photo diode (MPD), to produce a current signal indicative of the laser diode output power or intensity. Monitor photo diodes can be avalanche diodes and PIN photodiodes, among others.

In the case of the embodiment of FIG. 4A, the center of curvature of the biconic lens lies along a line 20 that is offset from the center axis 18′ of the fiber, which in this embodiment is aligned with the cavity axis 18 of laser diode 16. In other embodiments the center axis of the fiber is angled a few degrees from the cavity axis of the laser diode. In this way, a majority of the light output from the front facet 17 is captured and collected by biconic lens 12 but any reflected light off of the surface of lens 12 and propagating back into the laser cavity 21 of laser diode 16 is minimized. The amount of offset is dependent on the distance between the laser diode front facet 17 and the shape of biconic lens 12 as well as the size of the single mode core of fiber 14, but it may be in the range, for example, of several microns.

Reference is now made to FIG. 4B, which illustrates an angled chisel type lens 32, such as is discussed in U.S. Pat. No. 5,940,557, incorporated herein by reference, on a fiber end 30. As shown in FIG. 4B, the axis of lens 32 is angled with respect to the normal of the center axis 34 of fiber end 30. In the example here, the angle Θ₂ from the normal to the fiber longitudinal or optical axis 34 may be around 8°, which is exaggerated in FIG. 4B for purposes of illustration. The chisel lensed fiber input end 30 is shown in FIG. 4B with its central axis 34 aligned with the axis 18 of laser cavity 21. However, as shown in U.S. Pat. No. 5,940,557, the axis 18 of laser diode 16 may be aligned at an angle relative to the axis 34 of the fiber end 30.

The angled chisel lens 32 is used in combination with the laser diode 16 and laser monitor 15 to reduce tracking error. In particular, the angled chisel lens reduces the light from the aperture 18 of the front facet 17 reflected back into the laser cavity 21 that would be amplified and transmitted through the back facet 19 of the laser diode to the laser monitor 15. This amplified back reflected light can cause tracking error in the system because the light detected by the laser changes with the case temperature of the package.

FIG. 4C is a simplified top view of an optical fiber 14 according to an embodiment of the present invention illustrating a center 22 of the radius R of the lens 28 and how it is offset from the optical axis 34 of the fiber when viewed from the top. The optical axis 34 is essentially the center of the core 24 of the fiber 14. The center of the radius is offset about 2 microns from the optical axis of the core in a particular embodiment for a particular single-mode fiber. Other types of fibers might have different offsets. Thus, the center of the curved surface of the fiber end is also offset from the optical axis of the fiber, as viewed from the top. For purposes of discussion, this type of lens is called an offset biconic lens.

When aligning a fiber with an offset biconic lens to the output of a laser diode, the center axis of the fiber core can be aligned with the axis of the laser diode, without having to angle the fiber with respect to the laser diode output to avoid back reflections. In another embodiment, the laser diode is angled with respect to the center axis of the fiber, by about 2-15 degrees or about 2-5 degrees, which can improve coupling and further reduce back reflections. FIG. 4D is a simplified side view of the lensed fiber illustrated in FIG. 4C showing that the curve of the lens 28 is essentially centered with respect to the core 24 and center line 34 of the optical fiber 14 in this view, i.e. the center of curvature for the biconic lens in this section lies on the centerline 34.

In accordance with another embodiment of the invention, an angled biconic lens is used (not shown). A more detailed description is provided in U.S. application Ser. No. 09/915,186, incorporated herein by reference. The angled biconic lens is formed at an angle θ from the centerline of the fiber. This gives the lens a somewhat “bent” appearance. While the angled biconic lens could be angled on both axes, angling on one axis is desirable to reduce backreflections into a light source, while providing good coupling efficiency. The angle θ between the center axis of the fiber and the center axis of the lens is generally between about 2-12 degrees. In one embodiment, the center axis of the lens intersects the center axis of the fiber at the tip of the lens, although in other embodiments the tip of the lens might not be on the centerline of the fiber, but it is generally desirable to have the tip within the core portion of the fiber.

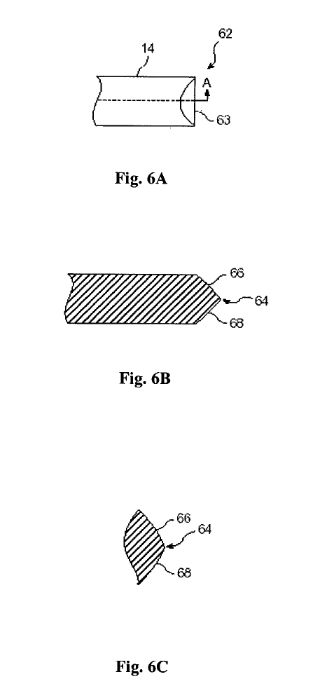

Another embodiment of an angled chisel lens is shown in FIGS. 5A-5C. In FIG. 5A, angled chisel lens 32A has an angled lens tip 35 such as around 8° from the normal to the longitudinal or optical axis of the fiber input end 30. The radius of curvature of lens tip 35 may be about 8 μm with a tapered angle Θ 1′ in the range of about 50° to 55°. Also, a part of the lens is shaved away at 33 so as to allow close positioning of the lens tip to laser diode 16. The distance between laser diode 16 and lensed fiber 14 is very small, such as, for example 10 μm. By angularly shaving off the lens at 33, the lens 32A can be positioned very close at an angle relative to laser diode facet 17 without contact of the facet by the lens. FIG. 5C is an end view of the lens 32A showing the lens tip 35 and the shaved portion 33, in addition to the faces of the lens.

In a typical application the chisel edge would lie essentially in a horizontal plane, but the fiber may be angled with respect to a laser diode or other light source. The radius at one end is different than the radius at the other end in a cylindrical embodiment. Other sectional shapes could be used to form the focusing structure on the chisel edge, such as a hyperbolic or a pointed shape, and both the shape and section could be varied. Advantageously, a cutaway region essentially truncates the chisel edge to provide clearance for aligning the fiber end close to a light source. The fiber may be angled with respect to the optical axis of the light source, with the end near the cutaway being placed closer to the source. The cutaway region allows the fiber end to be brought in close proximity to the light source.

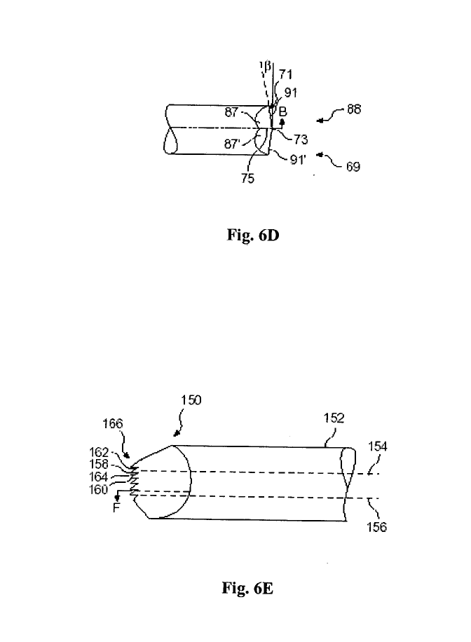

FIG. 6A is a simplified top view of another lens 62 on a fiber end that provides high coupling efficiency and low feedback when used to couple light from a laser diode. This lens 62 is a chisel lens that is nominally symmetrical about the optical axis (i.e. center of the core) of the optical fiber 14 and has an edge 63 that comes to a point. FIG. 6B is a section along A of the lens illustrated in FIG. 6A. The edge of the lens comes to a point 64 that is fabricated by lapping the fiber end at a radius offset from the center axis of the fiber on each side 66, 68 of the chisel lens. Although the edge of the chisel lens is shown as a straight segment in FIG. 4A, the edge could be curved, angled, or sharpened, as discussed above in relation to FIGS. 5A-5C.

FIG. 6C is an enlarged view of the point 64. Lapping at offset radii avoids the formation of a “flat” spot at the end of the fiber. Although lapping on a radius that lies along the center axis, as is conventionally done, produces a lensed fiber end with a very small radius of curvature, even such a small curvature can provide a surface that looks relatively flat to a light beam. This flatish surface can reflect light back into a laser diode, for example, while the point produced according to this embodiment provides much less reflection, even though the end of the lensed fiber is not a perfect point, that is to say, some softening of the point typically occurs due to the fabrication techniques. Other fabrication techniques, such as laser ablation or diamond turning, might be used to fabricate a pointed chisel lens.

FIG. 6D is a simplified top view of a double chisel lens 88. The term “double chisel” means that there are two angled chisel structures 69, 71 formed on the fiber end. Both chisel structures are angled with respect to a plane orthogonal to the center axis of the fiber and intersect to form a point 73. While the lens edge of the pointed chisel lens illustrated in FIG. 6A is pointed, the end of the double chisel lens comes to a “sharpened” point. In an alternate embodiment, one chisel is not angled and the other is. The point is preferably within or very near the core, and may be offset from the center of the core. The double chisel structure provides improved alignment tolerance because the cutaway portions of the fiber end avoid mechanical interference with the front facet of the source.

FIG. 6E is a simplified top view of a Fresnel-type chisel lens 150 on the end of an optical fiber 152. The core of the optical fiber is represented by dotted lines 154, 156. This type of lens avoids the lens tip getting too close to the facet of the laser diode when aligned in a source module. The Fresnel-type lens has a series of ridges 158, 160 and corresponding valleys 162, 164 formed on an edge 166 of the chisel structure. The ridges and valleys are very fine and at a fine pitch, typically much less than the core diameter, and are not drawn to scale, but are enlarged relative to the fiber for purposes of illustration. The lens structure is “broken” into these ridges and valleys, which for purposes of discussion will be referred to a “lenslets”, rather than angling a chisel lens. This avoids the variation in distance between one side of the lens structure and the other, compared to a conventional angled chisel lens.

Lensed fibers are often mounted at an angle to a laser diode source and in close proximity, about 8-10 microns away from the emitting facet in some cases. As described in the preceding paragraph, one face of the lens can be oriented toward the laser diode for optimized coupling. The other face of the lens serves as cut-away relief so that the fiber end can be mounted close to the laser diode without physical interference between the components.

In accordance with another embodiment of the invention, a fiber Bragg grating is formed in the pigtail fiber that is coupled to the laser diode. Methods of forming a fiber Bragg grating in a fiber are well known in the art. This fiber Bragg grating reflects a portion of the light from the laser diode back to the laser diode. The fiber Bragg grating causes said laser diode to operate in the coherence collapse regime.

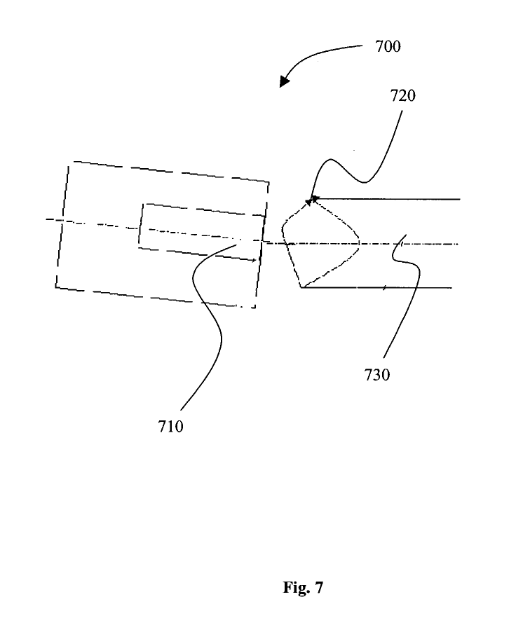

FIG. 7 presents a schematic view of a planar laser package 700 including an uncoated angled chisel lens 720 having a polarization-maintaining (PM) fiber pigtail with an integrated Bragg grating 730 coupled to a laser diode 710. The PM fiber pigtail with an integrated Bragg Grating and an uncoated lensed tip having a shape that produces minimal feedback into the optical cavity of a fiber amplifier pump module, allows the following performance improvements: spectral locking over a wide range of operating powers and temperatures, high kink free power independent of fiber lay, and increased damage threshold at high optical irradiance on the fiber facet. The invention improves spectral stability by simultaneously reviewing undesired feedback from the lens tip and stabilizing feedback from the grating. In accordance with this embodiment, the PM fiber portion of the pigtail is disposed between the lens tip and the fiber Bragg grating.

Advantageously, the present invention provides a laser module having good tracking error performance with relative insensitivity to fiber lay.

According to this invention, several solutions are provided for suppressing monitoring tracking error and/or maintaining intensity and spectral stability.

Tracking error results from uncontrolled variations in the ratio of fed-back light coming from the fiber Bragg grating compared to feedback coming from all other sources of feedback into the laser diode. By combining PM fiber, which more precisely fixes the level of feedback coming from the grating, with a controlled fiber tip shape that reduces the feedback coming from the fiber tip, reduced tracking error can be obtained.

Furthermore, since the feedback from the fiber tip is spectrally broadband, reducing this feedback in combination with the use of a PM fiber to provide narrow-band feedback can also improve the spectral stability of the laser.

A first embodiment of an improved laser diode module consists of a laser diode, coupled to a polarization-maintaining fiber that is oriented rotationally so that the polarization axes of the fiber are aligned with respect to the polarization of the light emitted from the laser diode. The tip of the fiber is formed with an angled chisel lens that is also oriented substantially along one of the polarization axes of the fiber.

Another embodiment of the improved laser diode module consists of a laser diode coupled to a PM fiber that is oriented rotationally so that the polarization axes of the fiber are aligned with respect to the polarization of the light emitted from the laser diode. The tip of the fiber is formed with a biconic lens, whose axes are oriented substantially along one of the polarization axes of the fiber.

A further embodiment of the improved laser diode module consists of a laser diode coupled to a PM fiber that is oriented rotationally so that the polarization axes of the fiber are aligned with respect to the polarization of the light emitted from the laser diode. The tip of the fiber is formed with an offset biconic lens, whose centerline is radially offset from the center of the PM fiber and whose axes are oriented substantially along one of the polarization axes of the fiber.

It is to be appreciated that there are many variations of fiber lens tip that can reduce the fiber tip reflection when combined with a polarization-maintaining fiber. The lens tip can be an approximation to an angled chisel or biconic formed by several facets, or a combination of straight and faceted segments. Furthermore, many hybrid shapes are possible with the same functionality of an angled chisel or an offset biconic if the lens does not possess an axis of symmetry that is an attribute of the prior art. Either a conical or conventional chisel lens is unchanged when rotated 180 degrees about the axis of the fiber. Any lens tip that does not possess this rotational symmetry will have improved tracking error when combined with a polarization-maintaining fiber. Several examples of suitable lens shapes are described heretofore.

It will further be appreciated that short segments of non-polarization-maintaining fiber may be introduced into the fiber span without degrading the performance of the module, as long as those segments do not experience substantial asymmetric stress, leading to stress-induced birefringence. Thus, the fiber lens tip could be fabricated in a short segment of conventional fiber, which is spliced to a longer segment of PM fiber. Alternatively, the fiber Bragg grating could be fabricated in a segment of normal fiber and spliced to a segment of PM fiber. Thirdly, the fiber between the laser diode and fiber Bragg grating could consist of multiple segments of PM fiber, as long as the major polarization axis of each segment is predominantly aligned to the major or minor polarization axis of its neighbor. These combinations can be combined singly or together without substantially deviating from the scope of the invention.

The invention has been tested on a 980 nm pump laser operated at 360 mW. Such a system was found to have very high kink-free powers to 360 mW. The laser module is provided in a planar package. Fiber Bragg grating (FBG) stabilization was used. Fiber Bragg grating wavelength stabilization of 980 nm pump modules greatly enhances their usefulness for Er-doped fiber amplifiers. Wavelength-stabilized 980 nm pump modules offer a nearly constant output spectrum over a wide variety of operating conditions combined with superior device to device reproducibility. Wavelength stabilization is realized by writing a slightly (several %) reflective, narrow-band FBG into the module pigtail, roughly 1 m away from the laser package. The majority of the pump laser light passes through the FBG, but several percent reflects back into the laser diode providing optical feedback. If the amount of reflected light is adequate, the optical feedback insures the laser operates only at the FBG wavelength, even as the drive current or temperature are varied widely. Other fetaures of the tested pump laser include available wavelength selection, tight tracking of fiber-coupled power, integrated thermoelectric cooler, thermistor, and monitor diode, high dynamic range, and excellent low power stability. Birefringence in the pigtail can be reduced by replacing the standard optical fiber between the laser and the FBG with polarization maintaining fiber. Any birefringence in the roundtrip optical path from the laser diode to the FBG reduces the amount of reflected light providing optical feedback. For example, if birefringence produces a polarization rotation near 90 degrees (or 270 degrees etc.), then there is little or no effective optical feedback, and the laser diode is decoupled from the FBG.

The use of an uncoated lens in such planar laser packages is advantageous with respect to fiber tail assembly cost, better line yield, reduced burn-in time, and reduced fiber tip damage when compared to AR coated microlenses.

Pump lasers in accordance with the invention find applications in next generation dense wavelength division multiplexing (DWDM) erbium doped fiber amplifiers (EDFAs) requiring the highest power with “locked” wavelength emission, reduced pump-count EDFA architectures, or very long distance CATV trunks and very high node count distribution.

The above described embodiments of the invention are intended to be examples of the present invention and numerous modifications, variations, and adaptations may be made to the particular embodiments of the invention without departing from the spirit and scope of the invention, which is defined in the claims.

What is claimed is:

1. A laser package comprising:
a single-mode laser diode for emitting light;
a single-mode optical fiber comprising an uncoated lens formed on an input end of said single-mode optical fiber, said lens optically coupled to the laser diode for receiving said light, said lens being constructed so as to reduce a level of back reflection into the laser diode so as not to disturb an operation of the laser diode, wherein a center axis of the single-mode optical fiber is co-planar with an optical axis of the laser diode; and
a grating formed in the single-mode optical fiber for providing feedback to the laser diode to stabilize the emitted light from the laser diode.

2. The laser package as defined in claim 1 wherein the single-mode laser diode is a high power single-mode laser diode.

3. The laser package as defined in claim 2 wherein the single-mode laser diode operates at an operating current of at least 360 mW.

4. The laser package as defined in claim 2 wherein the single-mode optical fiber comprises a length of polarization maintaining fiber between the grating and the single-mode laser diode.

5. The laser package as defined in claim 3 wherein the single-mode optical fiber comprises regular optical fiber between the laser diode and the grating.

6. The laser package as defined in claim 4 further comprising a light monitor optically coupled to the single-mode laser diode for monitoring an output power of the light emitted from the laser diode.

7. The laser package as defined in claim 6 wherein the light monitor is a monitor photo diode (MPD).

8. The laser package as defined in claim 6 wherein the laser diode operates at 980 nm.

9. The laser package as defined in claim 1 wherein the uncoated lens is one of a chisel lens, an angled chisel lens, a pointed chisel lens, a double chisel lens, a biconic lens, an angled biconic lens, an offset biconic lens, a Fresnel lens, a binary Fresnel lens, a toric lens, an a-toric lens, an offset toric lens, and an offset a-toric lens.

10. A planar laser package comprising:
a single-mode diode laser for emitting a beam of light;
a single-mode optical fiber optically coupled to the single mode diode laser, said single mode optical fiber having an uncoated microlens formed at an end face closest to the single-mode diode laser for receiving said beam of light, the microlens being constructed so as to reduce a level of back reflection into the single-mode laser diode; and
a fiber Bragg grating written into the single mode optical fiber for providing feedback to the single-mode laser diode for stabilizing the beam of light;
wherein the single-mode optical fiber comprises a length of polarization-maintaining fiber between the single-mode laser diode and the fiber Bragg grating.

11. The planar laser package as defined in claim 10 wherein the uncoated microlens is a chisel lens, an angled chisel lens, a pointed chisel lens, a double chisel lens, a biconic lens, an angled biconic lens, an offset biconic lens, a Fresnel lens, a binary Fresnel lens, a toric lens, an a-toric lens, an offset toric lens, or an offset a-toric lens.

12. The planar laser package as defined in claim 11 further comprising a light monitor optically coupled to the single-mode laser diode for monitoring an output power of the beam of light emitted by the laser diode.

13. A laser package comprising:
a single-mode laser diode source for emitting light;
a single-mode optical fiber optically coupled to the single-mode laser diode source for receiving said light; the single-mode laser diode source and the single-mode optical fiber being in a planar arrangement, wherein said single-mode optical fiber comprises an uncoated angled chisel lens, an uncoated angled biconic lens, or an uncoated offset biconic lens at an end face closest to the laser diode; and
a fiber Bragg grating formed within a portion of said single-mode optical fiber for providing feedback to said single-mode laser diode source,
wherein the single-mode optical fiber comprises a length of polarization-maintaining fiber between the single-mode laser diode and the fiber Bragg grating.

14. The laser package as defined in claim 13 wherein the single-mode laser diode source is a high power single-mode laser diode source.

15. The laser package as defined in claim 14 wherein the single-mode laser diode source operates at an operating current of at least 360 mW.

16. The laser package as defined in claim 13 wherein the single-mode laser diode source operates at 980 nm or 1480 nm.
